(19) United States
(12) Patent Application Publication
(10) Pub. No.: US 2025/0393241 A1
(43) Pub. Date: Dec. 25, 2025

(54) SEMICONDUCTOR DEVICE AND MANUFACTURING METHOD FOR SEMICONDUCTOR DEVICE

(71) Applicant: ROHM CO., LTD., Kyoto (JP)

(72) Inventor: Masahiro SAKURAGI, Kyoto (JP)

(73) Assignee: ROHM CO., LTD., Kyoto (JP)

(21) Appl. No.: 19/236,657

(22) Filed: Jun. 12, 2025

(30) Foreign Application Priority Data
Jun. 24, 2024 (JP) 2024-101105

(51) Int. Cl. H10D 30/65; H10D 30/01; H10D 62/10; H10D 62/60; H10D 64/23

(52) U.S. Cl. CPC H10D 30/655; H10D 30/0287; H10D 62/102; H10D 62/115; H10D 62/124; H10D 62/60; H10D 64/256

(57) ABSTRACT

A semiconductor device includes a first semiconductor layer of a first conductivity type that is positioned on a substrate, an insulator positioned in a recess provided in the first semiconductor layer, a second semiconductor layer of the first conductivity type positioned in the recess and at least directly below the insulator, an insulating layer positioned above the first semiconductor layer and the insulator, and a gate positioned on the insulating layer. The first semiconductor layer includes a source region and a drain region of the first conductivity type, a first impurity region positioned around the source region, and a second impurity region that is in contact with a bottom surface of the second semiconductor layer and that is of the first conductivity type. A diffusion coefficient for impurities in the second semiconductor layer is higher than a diffusion coefficient for impurities in the first semiconductor layer.

### CROSS REFERENCE TO RELATED APPLICATION

This application is based upon and claims the benefit of priority of the prior Japanese Patent Application No. 2024-101105, filed on Jun. 24, 2024, the entire contents of which are incorporated herein by reference.

### TECHNICAL FIELD

The present disclosure relates to a semiconductor device and a manufacturing method for a semiconductor device.

### BACKGROUND ART

WO/2021/161835 discloses a semiconductor device, including: a semiconductor chip having a main surface; a high potential region formed in a surface layer of the main surface; a low potential region formed in a surface layer of the main surface at a gap from the high potential region; a first conductivity-type drift region formed in a region between the high potential region and the low potential region in the surface layer of the main surface; and a first conductivity-type resurf region that is partially formed in a surface layer of the drift region so as expose, through the main surface, a portion of a region of the drift region to be a current path, and having an impurity concentration exceeding that of the drift region.

### BRIEF DESCRIPTION OF THE DRAWINGS

FIG. 1 is a schematic plan view of a semiconductor device according to an embodiment.

FIG. 2 is an expanded view of a device region including an LDMOS.

FIG. 3 is a schematic cross-sectional view along the III-III line of FIG. 2.

FIG. 4A is an expanded view of a relevant section of FIG. 3 encircled by the broken line.

FIG. 4B is an expanded cross-sectional view of a relevant section of a semiconductor device according to Modification Example 1.

FIG. 4C is an expanded cross-sectional view of a relevant section of a semiconductor device according to Modification Example 2.

FIG. 4D is an expanded cross-sectional view of a relevant section of a semiconductor device according to Modification Example 3.

FIG. 4E is an expanded cross-sectional view of a relevant section of a semiconductor device according to Modification Example 4.

FIG. 4F is an expanded cross-sectional view of a relevant section of a semiconductor device according to Modification Example 5.

FIG. 5 is a schematic cross-sectional view for describing a manufacturing method for an LDMOS included in the semiconductor device of Modification Example 5.

FIG. 6 is a schematic cross-sectional view for describing a manufacturing method for an LDMOS included in the semiconductor device of Modification Example 6.

FIG. 7 is a schematic cross-sectional view for describing a manufacturing method for an LDMOS included in the semiconductor device of Modification Example 7.

FIG. 8 is a schematic cross-sectional view for describing a manufacturing method for an LDMOS included in the semiconductor device of Modification Example 8.

FIG. 9 is a schematic cross-sectional view for describing a manufacturing method for an LDMOS included in the semiconductor device of Modification Example 9.

FIG. 10 is a schematic cross-sectional view for describing a manufacturing method for an LDMOS included in the semiconductor device of Modification Example 10.

FIG. 11 is a schematic cross-sectional view for describing a manufacturing method for an LDMOS included in the semiconductor device of Modification Example 11.

FIG. 12 is a schematic cross-sectional view for describing a manufacturing method for an LDMOS included in the semiconductor device of Modification Example 12.

FIG. 13 is a schematic cross-sectional view for describing a portion of a manufacturing method for the semiconductor device of the embodiment.

FIG. 14 is a schematic cross-sectional view for describing a portion of a manufacturing method for the semiconductor device of Modification Example 2.

FIG. 15 is a schematic cross-sectional view for describing a portion of a manufacturing method for the semiconductor device of Modification Example 3.

FIG. 16 is a schematic cross-sectional view for describing a portion of a manufacturing method for the semiconductor device of Modification Example 3.

FIG. 17 is a schematic cross-sectional view for describing a portion of a manufacturing method for the semiconductor device of Modification Example 4.

### DETAILED DESCRIPTION OF EMBODIMENTS

Below, an embodiment of the present disclosure will be explained in detail with reference to the attached drawings. In the description below, the same elements or elements having the same function are assigned the same reference character and redundant description thereof is omitted. Terms such as “same” or similar terms thereto in the present specification are not limited to situations in which the elements are identical. The drawings are for the purpose of conceptually explaining the embodiments, and thus, the dimensions and ratios thereof for the constituent elements depicted sometimes differ from reality.

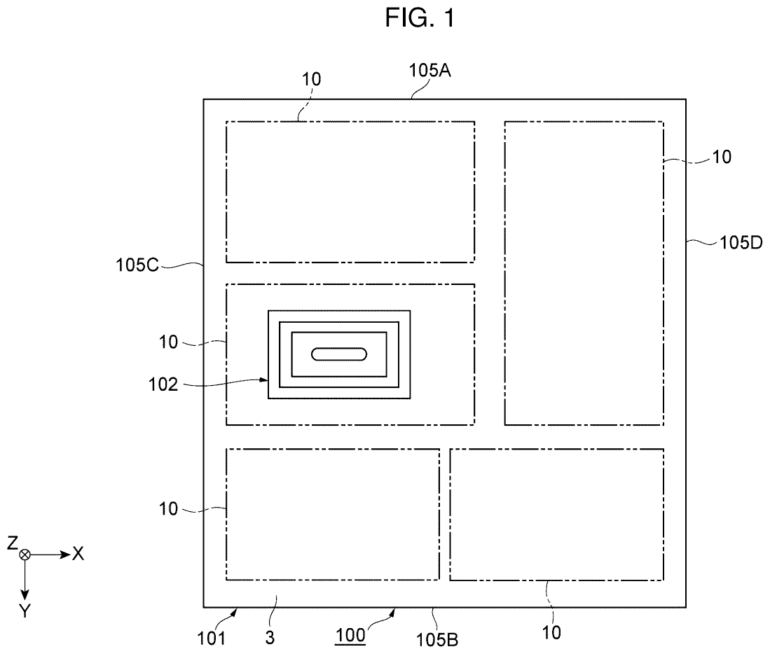

FIG. 1 is a schematic plan view of a semiconductor device according to the present embodiment. As shown in FIG. 1, a semiconductor device 100 includes a chip-type integrated circuit (IC), for example. The semiconductor device 100 may be referred to as a small scale IC (SSI), a middle scale IC (MSI), a large scale IC (LSI), a very large scale IC (VLSI), an ultra large scale IC (ULSI), or the like depending on the number of circuit elements integrated. The semiconductor device 100 is used as an LSI having installed therein a reference voltage circuit (VREF circuit), for example. In the present embodiment, the semiconductor device 100 includes a rectangular cuboid chip 101 (semiconductor chip).

The chip 101 includes a first main surface 103 that is the main surface, and a second main surface 104 that is the rear surface. The chip 101 has a first side face 105A, a second side face 105B, a third side face 105C, and a fourth side face 105D that connect the first main surface 103 and the second main surface 104. The thickness direction of the chip 101 corresponds to the Z axis direction, a direction orthogonal to the thickness direction corresponds to the X axis direction, and a direction orthogonal to both the Z axis direction and the X axis direction corresponds to the Y axis direction. Below, a view from the Z axis direction is designated as a plan view, and the direction extending along the X axis direction and the Y axis direction is designated as the planar direction. The direction towards the first main surface 103 in the Z axis direction is designated as the upward direction, and the direction towards the second main surface 104 in the Z axis direction is designated as the downward direction. Below, a view in the Z axis direction is also referred to simply as a plan view.

The first main surface 103 and the second main surface 104 are surfaces extending in a direction perpendicular to the Z axis direction. The plan view shape of the first main surface 103 and the plan view shape of the second main surface 104 are quadrilaterals, but the shapes thereof are not limited thereto. The first side face 105A and the second side face 105B both extend along the X axis direction in a plan view. The third side face 105C and the fourth side face 105D both extend along the Y axis direction in a plan view.

The semiconductor device 100 includes a plurality of device regions 10. A gap is provided between each device region 10 and each side face (first side face 105A to fourth side face 105D) of the chip 101. The number, arrangement, and shape of the device regions 10 is not limited to any specific number, arrangement, or shape. Various devices are formed in each of the device regions 10. The devices can include at least one of the following, for example: a semiconductor switching device such as a high-side switch or a low-side switch; a semiconductor rectifier device; and a passive device. The semiconductor switching device may include at least one of a junction field effect transistor (JFET), a metal-insulator-semiconductor field effect transistor (MISFET; insulated gate field effect transistor), a bipolar junction transistor (BJT), and an insulated gate bipolar junction transistor (IGBT).

A metal-oxide-semiconductor field effect transistor (MOSFET) can be used as the MISFET. The MOSFET may be of the enhancement type or the depletion type. The MOSFET may have a planar structure or a vertical structure. The MISFET can also be a power transistor. Examples of a drain-source voltage of the MISFET include high voltage HV (e.g., 100V to 1,000V, inclusive), middle voltage MV (e.g., 30V to 100V, inclusive), and low voltage LV (e.g., 1V to 30V, inclusive). Otherwise, the device region 10 may include an optical device such as a light emission element or a light reception element.

In the present embodiment, the semiconductor material constituting the chip 101 is silicon (Si), but is not limited thereto. The semiconductor material constituting the chip 101 can also be a compound semiconductor. Such compound semiconductors include III-V compound semiconductors, IV-IV compound semiconductors, or mixed crystal semiconductors including the foregoing semiconductors. The III-V compound semiconductors are Ga-containing semiconductors such as GaAs and GaN, for example. The IV-IV compound semiconductors are Si-containing semiconductors such as SiC and SiGe, for example.

At least one of the plurality of device regions 10 has formed therein a lateral double-diffused MOS (LDMOS) 102. Below, the structure of the LDMOS 102 will be described.

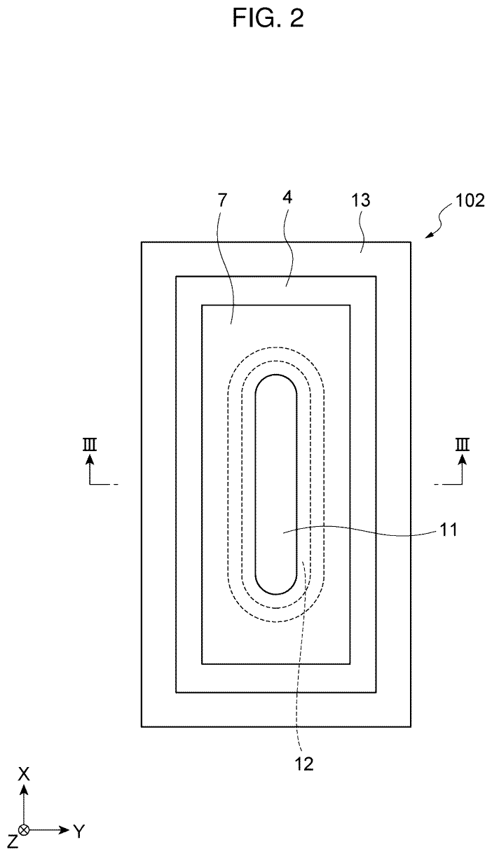

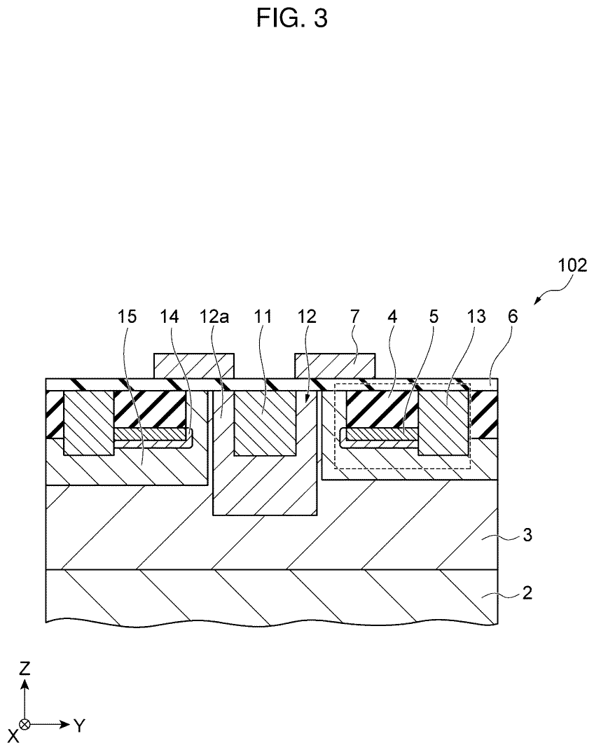

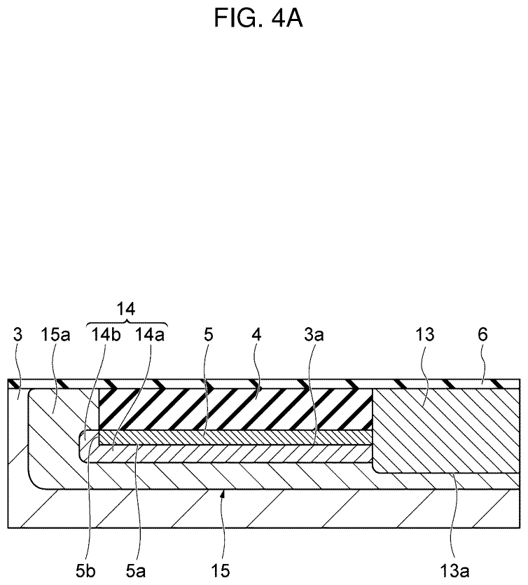

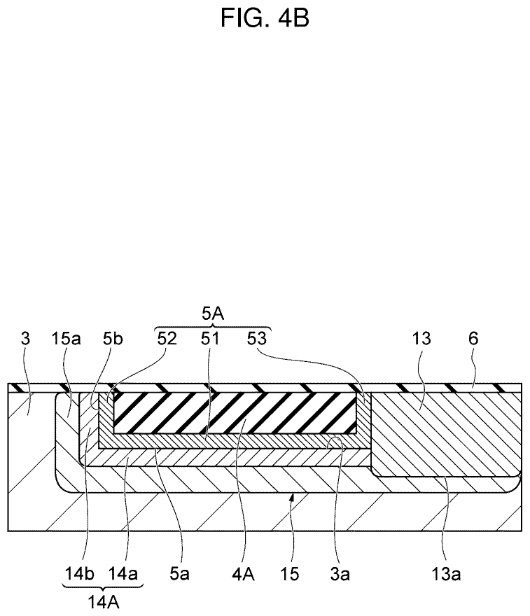

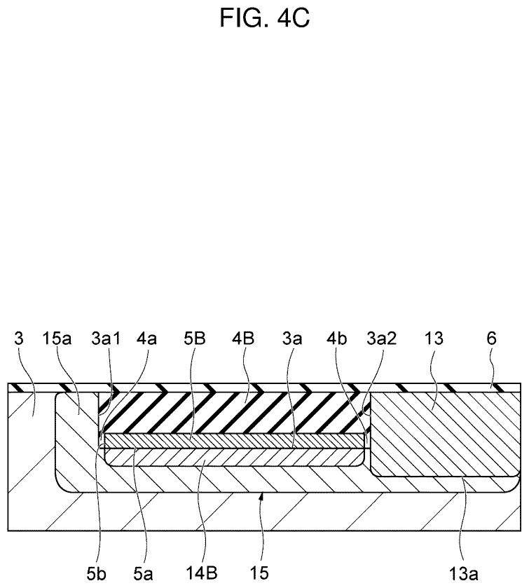

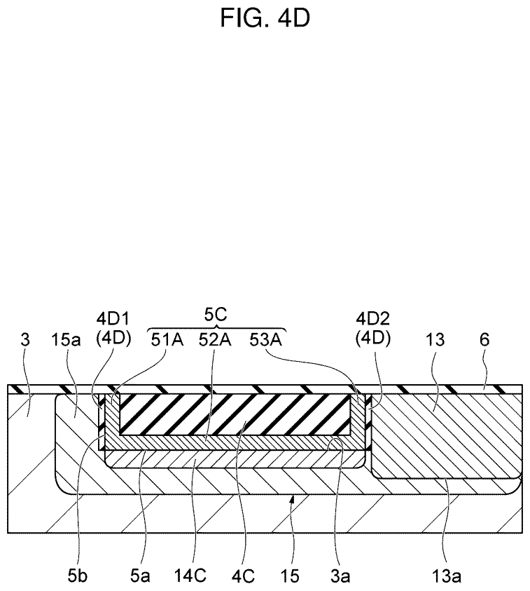

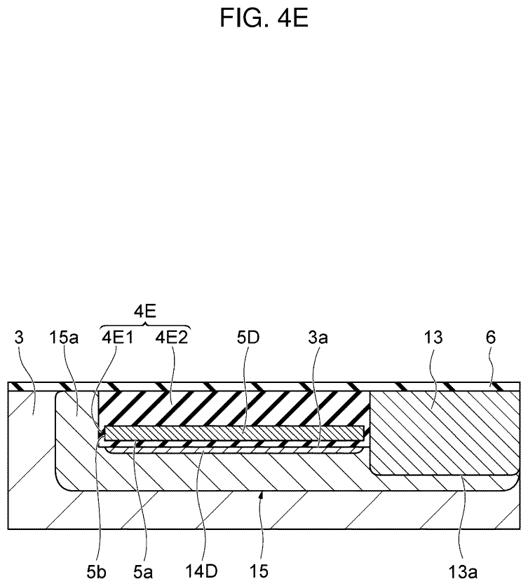

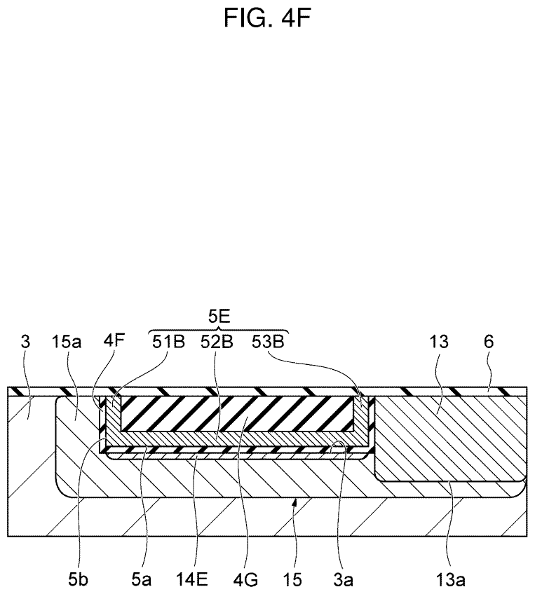

FIG. 2 is an expanded view of the device region 10 including the LDMOS 102, and FIG. 3 is a schematic cross-sectional view along the III-III line of FIG. 2. FIG. 4A is an expanded view of a relevant section of FIG. 3 encircled by the broken line. As shown in FIGS. 2, 3, and 4A, the LDMOS 102 includes a substrate 2, a first semiconductor layer 3 that is positioned on the substrate 2 and that is of a first conductivity type, an insulator 4 positioned on the first semiconductor layer 3, a second semiconductor layer 5 positioned directly below the insulator 4, an insulating layer 6 positioned on the first semiconductor layer 3 and the insulator 4, and a gate 7 positioned on the insulating layer 6. Although not shown, the LDMOS 102 is surrounded by an element isolation structure. In the present embodiment, the first conductivity type is the n type and the second conductivity type is the p type, but the configuration is not limited thereto. The first conductivity type may instead be the p type, with the second conductivity type being the n type. In FIG. 2, the insulating layer 6 is omitted.

Although not shown, an embedded region of the second conductivity type may be formed at the boundary between the substrate 2 and the first semiconductor layer 3 and the vicinity thereof. If the embedded region is formed, in one example the embedded region would be formed so as to straddle the boundary between the substrate 2 and the first semiconductor layer 3. The thickness of the embedded region is 1 μm to 3 μm, inclusive, for example. The embedded region is isolated from a body region, a resurf region, and the like, which will be described later.

In the present embodiment, the substrate 2 is a high-resistance silicon substrate of the second conductivity type. The impurity concentration of the substrate 2 is set to be relatively low. In the present embodiment, the impurity concentration of the substrate 2 may be 1.0×10¹³ cm⁻³ to 1.0×10¹⁴ cm⁻³, inclusive, for example.

The first semiconductor layer 3 is a crystal layer formed on the substrate 2. In one example, the first semiconductor layer 3 is an epitaxial layer (single crystal layer) with the substrate 2 as the seed. The impurity concentration of the first semiconductor layer 3 may be 1.0×10¹⁵ cm⁻³ to 1.0×10¹⁶ cm⁻³, inclusive, for example. The thickness of the first semiconductor layer 3 is 1 μm to 10 μm, inclusive, for example. A recess 3a where the insulator 4 and the second semiconductor layer 5 are positioned is provided in the first semiconductor layer 3. The recess 3a has a substantially elliptical loop shape in a plan view. The recess 3a has a depth of 100 nm to 1,000 nm, inclusive, in the Z axis direction.

The first semiconductor layer 3 has a source region 11 (first contact region), a body region 12 (first impurity region), a drain region 13 (second contact region), a first resurf region 14 (second impurity region), and a second resurf region 15 (third impurity region). If the embedded region is formed in the first semiconductor layer 3, then the source region 11, the body region 12, the drain region 13, the first resurf region 14, and the second resurf region 15 are all isolated from the embedded region.

The source region 11 is a region that forms a portion of the current path of the LDMOS 102 and serves as the source of the LDMOS 102, and is of the first conductivity type. The source region 11 is provided in at least the surface of the first semiconductor layer 3, and is a contact region that is in contact with wiring (not shown). A source potential is applied to the source region 11 from outside the semiconductor device 100 via the wiring, for example. In one example, the source region 11 has an elliptical shape in a plan view. The dimension of the source region 11 along the Z axis direction is 0.1 μm to 0.5 μm, inclusive, for example. The impurity concentration of the source region 11 may be 1.0×10¹⁸ cm⁻³ to 1.0×10²¹ cm⁻³, inclusive, for example.

The body region 12 is a region (well region) that covers the bottom and sides of the source region 11, and is of the second conductivity type. In one example, the body region 12 has an elliptical loop shape that surrounds the source region 11 in a plan view, and is in contact with the source region 11. Thus, a portion 12a of the body region 12 is positioned closer to the drain region 13 than the source region 11. The portion 12a is at least provided in the surface of the first semiconductor layer 3, overlaps the gate 7 in the Z axis direction, and can form a portion of the current path of the LDMOS 102. The portion 12a can function as the channel of the LDMOS 102. The dimension of the body region 12 along the Z axis direction is 0.1 μm to 3 μm, inclusive, for example. The impurity concentration of the body region 12 may be 1.0×10¹⁶ cm⁻³ to 1.0×10¹⁸ cm⁻³, inclusive, for example. The body region 12 may have an elliptical loop shape, or a polygonal loop shape such as a quadrilateral loop shape in a plan view.

The drain region 13 is a region that forms a portion of the current path of the LDMOS 102 and serves as the drain of the LDMOS 102, and is of the first conductivity type. The drain region 13 is provided in at least the surface of the first semiconductor layer 3, and is a contact region that is in contact with wiring (not shown). A drain potential is applied to the drain region 13 from outside the semiconductor device 100 via the wiring, for example. In one example, the drain region 13 has a quadrilateral loop shape that surrounds the source region 11 and the gate 7 in a plan view, but the configuration is not limited thereto. The drain region 13 may have an elliptical loop shape or the like in a plan view. The dimension of the drain region 13 along the Z axis direction is 0.1 μm to 0.5 μm, inclusive, for example. The impurity concentration of the drain region 13 may be 1.0×10¹⁸ cm⁻³ to 1.0×10²¹ cm⁻³, inclusive, for example.

The first resurf region 14 is a region that is positioned around the drain region 13 and that is in contact with at least a bottom surface 5a of the second semiconductor layer 5, and is of the first conductivity type. In the present embodiment, the first resurf region 14 is in contact with a portion of the drain region 13, but the configuration is not limited thereto. The first resurf region 14 may overlap the gate 7 in the Z axis direction. The first resurf region 14 can, similar to the drain region 13, form a portion of the current path of the LDMOS 102. The first resurf region 14 is formed as a result of impurities in the second semiconductor layer 5 diffusing to the first semiconductor layer 3 (details to follow). Thus, the first resurf region 14 is formed around the second semiconductor layer 5. The impurity concentration of the first resurf region 14 is greater than the impurity concentration of the second resurf region 15, and is 1.0×10¹⁷ cm⁻³ to 1.0×10²⁰ cm⁻³, inclusive, for example.

In the present embodiment, the first resurf region 14 has a first impurity section 14a in contact with the bottom surface 5a of the second semiconductor layer 5 in the Z axis direction, and a second impurity section 14b positioned closer to the source region 11 than the first impurity section 14a in the Y axis direction. The first impurity section 14a is a section in contact with the drain region 13. The second impurity section 14b is in contact with a side face 5b of the second semiconductor layer 5, and is a section positioned between the source region 11 and the second semiconductor layer 5. A portion of the second impurity section 14b may be in contact with the insulator 4. The second impurity section 14b is isolated from the insulating layer 6, but the configuration is not limited thereto.

The second resurf region 15 is a region that is positioned around the first resurf region 14 and that is in contact with at least the drain region 13, and is of the first conductivity type. In the present embodiment, the second resurf region 15 is in contact with the bottom surface 13a of the drain region 13 and the first resurf region 14, and surrounds the first resurf region 14. The second resurf region 15 is isolated from the body region 12. The second resurf region 15 can, similar to the drain region 13 and the first resurf region 14, form a portion of the current path of the LDMOS 102. A portion 15a of the first resurf region 15 is positioned closer to the source region 11 than the insulator 4 in the Y axis direction, and overlaps the gate 7 in the Z axis direction. The impurity concentration of the second resurf region 15 is less than the impurity concentration of the first resurf region 14, and is 1.0×10¹⁵ cm⁻³ to 1.0×10¹⁸ cm⁻³, inclusive, for example.

The insulator 4 is positioned within the recess 3a of the first semiconductor layer 3, and overlaps the second semiconductor layer 5 in the Z axis direction. In the present embodiment, the entire insulator 4 is an embedded insulator positioned on the second semiconductor layer 5 in the Z axis direction (shallow trench isolation (STI)). The insulator 4 may be an oxide insulator such as silicon oxide or aluminum oxide, or a nitride insulator such as silicon nitride, for example. The thickness of the insulator 4 is adjusted as appropriate according to the depth of the recess 3a and the thickness of the second semiconductor layer 5, and is 100 nm to 800 nm, inclusive, for example.

The second semiconductor layer 5 is a semiconductor layer positioned within the recess 3a of the first semiconductor layer 3 and directly below the insulator 4, and is of the first conductivity type. The second semiconductor layer 5 covers the entire bottom surface of the recess 3a but the configuration is not limited thereto. In the present embodiment, the second semiconductor layer 5 is a semiconductor layer having a lower crystallinity than the first semiconductor layer 3, and is a polysilicon layer, for example. In other words, the crystallizability of the second semiconductor layer 5 is lower than the crystallizability of the first semiconductor layer 3. Thus, the diffusion coefficient for impurities or the like present in the second semiconductor layer 5 is higher than the diffusion coefficient for impurities or the like present in the first semiconductor layer 3. In one example, the diffusion coefficient for impurities in the second semiconductor layer 5 is five to 500 times the diffusion coefficient for impurities in the first semiconductor layer 3. The second semiconductor layer 5 is deposited in the recess 3a by a publicly known means such as chemical vapor deposition (CVD), for example. The thickness of the second semiconductor layer 5 is 10 nm to 500 nm, inclusive, for example. The impurity concentration of the second semiconductor layer 5 may be 1.0×10¹⁷ cm⁻³ to 1.0×10²⁰ cm⁻³, inclusive, for example.

The insulating layer 6 is an insulating layer (gate insulating film) provided on the surface of the first semiconductor layer 3, and is positioned between the first semiconductor layer 3 and the gate 7. The insulating layer 6 may have a single-layer structure or a multilayer structure. The insulating layer 6 may be made of an oxide insulator such as silicon oxide or aluminum oxide, or may be made of a nitride insulator such as silicon nitride, for example. The insulating layer 6 may contain a local oxidation of silicon (LOCOS) film made through selective oxidation of the first semiconductor layer 3. Although not shown, the insulating layer 6 is provided with an opening for exposing a portion of the source region 11, an opening for exposing a portion of the drain region 13, and the like.

The gate 7 is a conductor positioned on the insulating layer 6, and has a frame shape surrounding the source region 11 in a plan view. The gate 7 contains a metal film, an alloy film, conductive polysilicon, or the like, for example. If the gate 7 contains conductive polysilicon, then the conductive polysilicon can include a first conductivity-type impurity or a second conductivity-type impurity from the perspective of the conductivity of the gate 7. A portion of the gate 7 is positioned between the source region 11 and the drain region 13 in the Y axis direction, as seen in a plan view. At least a portion of the first semiconductor layer 3 overlapping the gate 7 functions as the channel region of the LDMOS 102. The channel region is positioned between the body region 12 and the second resurf region 15 in the first semiconductor layer 3, for example. In the channel region, the current path between the source region 11 and the drain region 13 is controlled to be conductive or non-conductive according to the potential applied to the gate 7.

In the LDMOS 102 included in the semiconductor device 100 according to the present embodiment described above, the second semiconductor layer 5 is positioned directly below the insulator 4, which is an STI. Here, the diffusion coefficient for impurities in the second semiconductor layer 5 is higher than the diffusion coefficient for impurities in the first semiconductor layer 3. As a result, during manufacture of the semiconductor device 100, the impurities in the second semiconductor layer 5 diffuse to the first semiconductor layer 3 (details to follow). As a result, the first resurf region 14 having the higher impurity concentration is selectively provided below and in the vicinity of the insulator 4. That is, it is possible to selectively form the first resurf region 14 thinly and directly below the recess 3a. Thus, it is possible to achieve a balance between a high withstand voltage and a decrease in ON resistance of the LDMOS 102.

Typically, the first resurf region is formed by a similar method to the above-mentioned second resurf region 15 (i.e., the introduction of impurities to the first semiconductor layer 3). In this case, there is a tendency for variation in the shape, depth, and the like in the first resurf region due to variations in shape, quality, and the like of the insulator 4. On the other hand, in the LDMOS 102 included in the semiconductor device 100 according to the present embodiment, even if there is variation in the shape, quality, and the like of the insulator 4, variation in the shape or the like of the first resurf region 14 can be sufficiently suppressed. By adjusting the impurity concentration, the formation position, the thickness, and the like of the second semiconductor layer 5, it is possible to adjust the performance and shape of the first resurf region 14. Thus, according to the present embodiment, the characteristics of the first resurf region 14, and by extension, the withstand voltage and ON resistance of the LDMOS 102 can be easily and stably adjusted.

Next, semiconductor devices according to modification examples will be described with reference to FIGS. 4B to 4F. Below, explanation of sections in common with the embodiment above will be omitted.

FIG. 4B is an expanded cross-sectional view of a relevant section of a semiconductor device according to Modification Example 1. As shown in FIG. 4B, the semiconductor device according to Modification Example 1 differs from the embodiment above in that an insulator 4A and a second semiconductor layer 5A are formed in the recess 3a of the first semiconductor layer 3. The second semiconductor layer 5A covers the entire surface of the recess 3a. The second semiconductor layer 5A has a first portion 51 positioned directly below the insulator 4A, a second portion 52 positioned between the insulator 4A and the body region 12 in the Y axis direction, and a third portion 53 positioned between the insulator 4A and the drain region 13 in the Y axis direction. The second portion 52 and the third portion 53 are both in contact with the insulating layer 6. In addition, the third portion 53 and the drain region 13 are in contact with each other. The insulator 4A is surrounded by the second semiconductor layer 5A in the recess 3a. Thus, the insulator 4A is isolated from the first semiconductor layer 3.

In Modification Example 1, as a result of the second semiconductor layer 5A being formed in the recess 3a, the second impurity section 14b included in the first resurf region 14A is in contact with the insulating layer 6. Therefore, the second impurity section 14b is positioned between the source region 11 and the second portion 52 of the second semiconductor layer 5A. The second impurity section 14b in Modification Example 1 can be said to spread to a greater degree than in the embodiment above.

A similar effect to the embodiment above is also exhibited by Modification Example 1 described above. In addition, in Modification Example 1, the second semiconductor layer 5A has the third portion 53, and thus, a current more readily flows to the first resurf region 14A from the drain region 13 and through the second semiconductor layer 5A. Furthermore, the first resurf region 14A (in particular, the second impurity section 14b) has spread to a greater degree than in the embodiment above. Thus, in Modification Example 1, the ON resistance of the LDMOS can be sufficiently reduced.

FIG. 4C is an expanded cross-sectional view of a relevant section of a semiconductor device according to Modification Example 2. As shown in FIG. 4C, the semiconductor device according to Modification Example 2 differs from the embodiment above in that the side face of the second semiconductor layer 5B is isolated from the recess 3a of the first semiconductor layer 3. In other words, an insulator (second insulator) differing from the embodiment above is provided between an inner side face of the second semiconductor layer 5B and a side face 3a1 of the recess 3, and between an outer side face of the second semiconductor layer 5B and a side face 3a2 of the recess 3. In Modification Example 2, the second semiconductor layer 5B covers a portion of the bottom surface of the recess 3a, and the insulator 4B has a first insulating section 4a positioned between the second semiconductor layer 5B and the side face 3a1 of the recess 3a, and a second insulating section 4b positioned between the second semiconductor layer 5B and the side face 3a2 of the recess 3a. The first insulating section 4a and the second insulating section 4b are components corresponding to the second insulator. The first insulating section 4a is a section that covers the inner side face of the second semiconductor layer 5B and has an elliptical shape along the side face 3a1. The first insulating section 4b is a section that covers the outer side face of the second semiconductor layer 5B and has an elliptical shape along the side face 3a2. From the perspective of the ON resistance or the like of the LDMOS 102, the width of the first insulating section 4a and the width of the second insulating section 4b are 2% to 15%, inclusive, of the width of the recess 3a, for example.

In Modification Example 2, as a result of the insulator 4B and the second semiconductor layer 5B being formed, the first resurf region 14B is formed only directly below the recess 3a, but the configuration is not limited thereto. Depending on the degree of impurity diffusion from the second semiconductor layer 5B, a portion of the first resurf region 14B may be positioned between the recess 3a and the source region 11. In other words, the portion of the first resurf region 14B may be positioned between the side face 3a1 and the source region 11.

A similar effect to the embodiment above is also exhibited by Modification Example 2 described above. In addition, in Modification Example 2, the first resurf region 14B is either not formed or is less likely to be formed between the source region 11 and the second semiconductor layer 5B. As a result, it is possible to suitably realize an increased withstand voltage for the LDMOS according to Modification Example 2.

FIG. 4D is an expanded cross-sectional view of a relevant section of a semiconductor device according to Modification Example 3. As shown in FIG. 4D, the semiconductor device according to Modification Example 3 differs from Modification Example 1 in that the side faces 3a1 and 3a2 of the recess 3a of the first semiconductor layer 3 are covered by the second insulator 4D. Thus, similar to Modification Example 1, in Modification Example 3, the second semiconductor layer 5C including the first portion 51A, the second portion 52A, and the third portion 53A, and the insulator 4C surrounded by the second semiconductor layer 5C in the recess 3a are formed. However, in Modification Example 3, the second portion 52A and the third portion 53A are isolated from the first semiconductor layer 3.

The second insulator 4D includes a first insulating section 4D1 positioned between the side face 3a1 of the recess 3a and the second portion 52A of the second semiconductor layer 5C, and a second insulating section 4D2 positioned between the side face 3a2 of the recess 3a and the third portion 53A of the second semiconductor layer 5C. The first insulating section 4D1 and the second insulating section 4D2 are simultaneously formed by selective etching of the insulating film covering the recess 3a, for example. In one example, the first insulating section 4D1 has a similar shape to the first insulating section 4a of Modification Example 2, and the second insulating section 4D2 has a similar shape to the second insulating section 4b of Modification Example 2.

In Modification Example 3, as a result of the second insulator 4D and the second semiconductor layer 5C being formed, the first resurf region 14C is formed only directly below the recess 3a, but the configuration is not limited thereto. Depending on the impurity diffusion from the second semiconductor layer 5C, a portion of the first resurf region 14C may be positioned between the recess 3a and the source region 11.

A similar effect to Modification Example 2 is also exhibited by Modification Example 3 described above. In addition, in Modification Example 3, a large quantity of impurities are included in the second semiconductor layer 5C, and thus, the impurity concentration of the first resurf region 14C can be sufficiently increased. Thus, the ON resistance of the LDMOS according to Modification Example 3 can be sufficiently reduced.

FIG. 4E is an expanded cross-sectional view of a relevant section of a semiconductor device according to Modification Example 4. As shown in FIG. 4E, the semiconductor device according to Modification Example 4 differs from the embodiment above in that the entire second semiconductor layer 5D is isolated from the first semiconductor layer 3. Specifically, an insulating layer 4E1 included in an insulator 4E is positioned between the first semiconductor layer 3 and the second semiconductor layer 5D. The insulating layer 4E1 is an insulator formed as a layer positioned on the surface of the recess 3a. In one example, the insulating layer 4E1 is formed by CVD, oxidation, or the like before the second semiconductor layer 5D is formed. From the perspective of suitably diffusing impurities from the second semiconductor layer 5D to the first semiconductor layer 3, the thickness of the insulating layer 4E1 is 5 nm to 50 nm, inclusive, for example. An insulating section 4E2 included in the insulator 4E is a section corresponding to the insulator 4 of the embodiment above. In Modification Example 4, the insulating layer 4E1 and the insulating section 4E2 are integrated, and thus, the insulator 4E is formed in the recess 3a.

In Modification Example 4, as a result of the insulator 4E (in particular, the insulating layer 4E1) and the second semiconductor layer 5D being formed, the first resurf region 14D is formed only directly below the recess 3a, but the configuration is not limited thereto. Depending on the impurity diffusion from the second semiconductor layer 5D, a portion of the first resurf region 14D may be positioned between the recess 3a and the source region 11. By partially adjusting the thickness of the insulating layer 4E1, the first resurf region 14D is formed only directly below the recess 3a.

A similar effect to the embodiment above is also exhibited by Modification Example 4 described above. In addition, in Modification Example 4, there is no contact between the second semiconductor layer 5D and the first semiconductor layer 3, and thus, no defects resulting from contact occur in the LDMOS. Additionally, in Modification Example 4, the first resurf region 14D can be thinned sufficiently.

FIG. 4F is an expanded cross-sectional view of a relevant section of a semiconductor device according to Modification Example 5. As shown in FIG. 4F, similar to Modification Example 4, the semiconductor device according to Modification Example 5 differs from the embodiment above in that the entire second semiconductor layer 5E is isolated from the first semiconductor layer 3. In Modification Example 5, an insulating layer 4F is positioned between the first semiconductor layer 3 and the second semiconductor layer 5E. The insulating layer 4F is an insulator formed as a layer, similar to the insulating layer 4E1 of Modification Example 4. Similar to the Modification Example 3, the second semiconductor layer 5E has a first portion 51B, a second portion 52B, and a third portion 53B. Similar to Modification Example 3, the insulating layer 4F is positioned between the side face 3a1 of the recess 3a and the second portion 52B of the second semiconductor layer 5E, and between the side face 3a2 of the recess 3a and the third portion 53B of the second semiconductor layer 5E. Also, similar to Modification Example 3, the insulator 4G surrounded by the second semiconductor layer 5E in the recess 3a is formed.

In Modification Example 5, as a result of the insulating layer 4F and the second semiconductor layer 5E being formed, the first resurf region 14E is formed only directly below the recess 3a, but the configuration is not limited thereto. Depending on the degree of impurity diffusion from the second semiconductor layer 5E, a portion of the first resurf region 14E may be positioned between the recess 3a and the source region 11. By partially adjusting the thickness of the insulating layer 4F, the first resurf region 14E is formed only directly below the recess 3a.

A similar effect to Modification Example 4 can also be exhibited by Modification Example 5 described above.

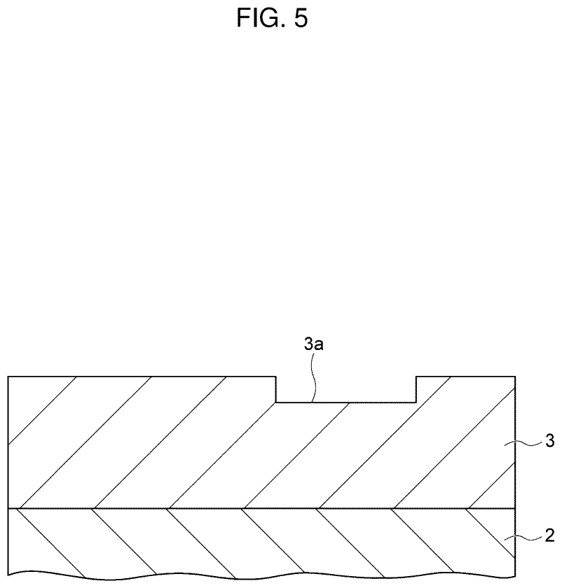

Next, an example of a manufacturing method for the LDMOS included in the semiconductor device according to Modification Example 5 will be described with reference to FIGS. 5 to 12. FIGS. 5 to 12 are schematic cross-sectional views for describing the manufacturing method for the LDMOS included in the semiconductor device of Modification Example 5.

First, as shown in FIG. 5, the recess 3a is formed in the first semiconductor layer 3 positioned on the substrate 2 and being of the first conductivity type (first step). In the first step, the first semiconductor layer 3 that is a single-crystal semiconductor layer is formed by epitaxial growth of the first semiconductor layer 3 on the substrate 2, for example. Here, the formation of the first semiconductor layer 3 may be performed after doping a portion of the substrate 2 with second conductivity-type impurities. In this case, an embedded region (not shown) can be formed. Next, the recess 3a is formed in the first semiconductor layer 3. For example, a mask (not shown) is selectively formed on the first semiconductor layer 3, after which the recess 3a is formed through selective etching of the first semiconductor layer 3 using the mask. In this example, the mask is a silicon oxide film, but the material of the mask is not limited thereto. The first semiconductor layer 3 may be dry-etched or wet-etched.

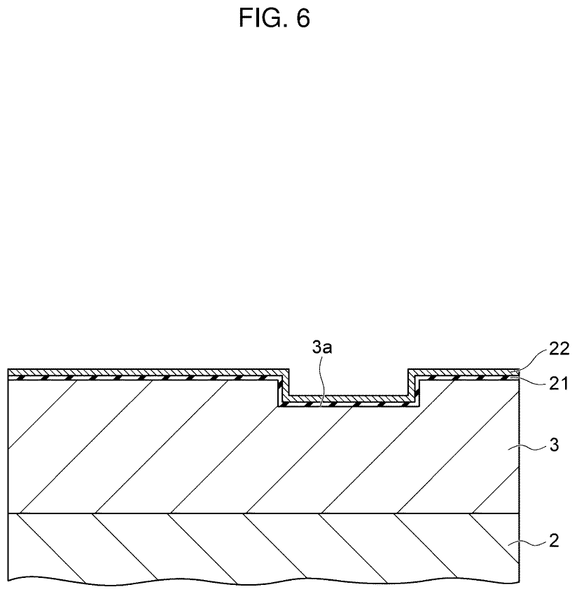

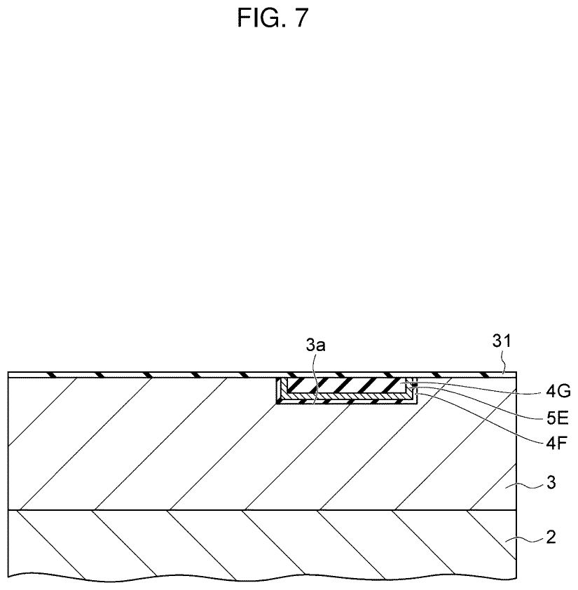

Next, as shown in FIGS. 6 and 7, the insulating layer 4F and the second semiconductor layer 5E are formed in the recess 3a of the first semiconductor layer 3 (second step), after which the insulator 4G covering at least a portion of the second semiconductor layer 5E in the recess 3a is formed (third step). In the second step, as shown in FIG. 6, an insulating layer 21 and a semiconductor layer 22 are first formed sequentially on the first semiconductor layer 3. The insulating layer 21 is an insulator formed as a layer to become the insulating layer 4F (second insulating layer) later, and covers the surface of the recess 3a. The semiconductor layer 22 is a semiconductor formed as a layer to become the second semiconductor layer 5E later, and is positioned on the insulating layer 21. The diffusion coefficient for impurities in the semiconductor layer 22 is higher than the diffusion coefficient for impurities in the first semiconductor layer 3. Next, although not shown, portions of the insulating layer 21 and the semiconductor layer 22 present outside of the recess 3a are removed. Such portions are removed through selective etching using a mask (not shown), for example. Thus, as shown in FIG. 7, the insulating layer 4F and the second semiconductor layer 5E are formed.

Next, in the third step, the insulator 4G is selectively formed so as to embed the recess 3a. Then, a cover film 31 is formed over the first semiconductor layer 3, the insulating layer 4F, the second semiconductor layer 5E, and the insulator 4G. The cover film 31 is an insulating film formed to protect the surface and the like of the first semiconductor layer 3. The cover film 31 is formed by a publicly known method such as CVD, for example. In one example, the cover film 31 is a silicon oxide film, but the material is not limited thereto.

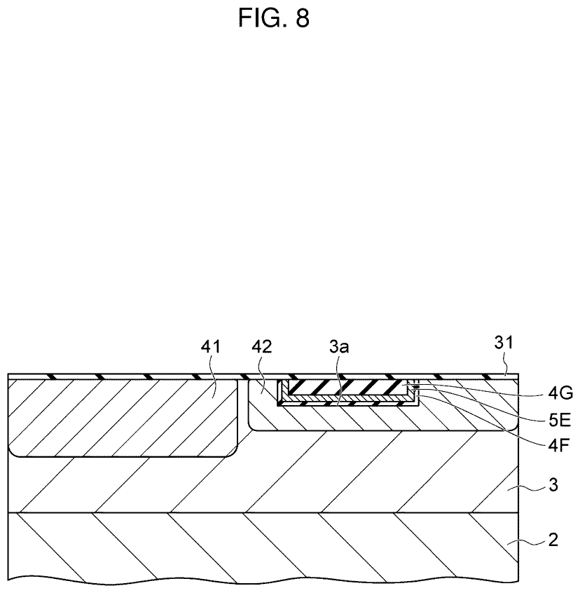

Next, as shown in FIG. 8, the impurity region 41 of the second conductivity type is formed in the first semiconductor layer 3 (fourth step). In the fourth step, a mask (not shown) is used to introduce (dope) impurities of the second conductivity type to a portion of the first semiconductor layer 3, thereby forming the impurity region 41. The impurity region 41 is a region to become the body region 12 later, and is isolated from the recess 3a. By providing the cover film 31, the surface of the first semiconductor layer 3 is less susceptible to damage when introducing the impurities to the first semiconductor layer 3. Immediately before or after the fourth step, the impurity region 42 of the second conductivity type is formed in the first semiconductor layer 3. Another mask (not shown) is used to introduce impurities of the first conductivity type to a portion of the first semiconductor layer 3, thereby forming the impurity region 42. The impurity region 42 is a region to become the second resurf region 15 later, and is provided around the recess 3a.

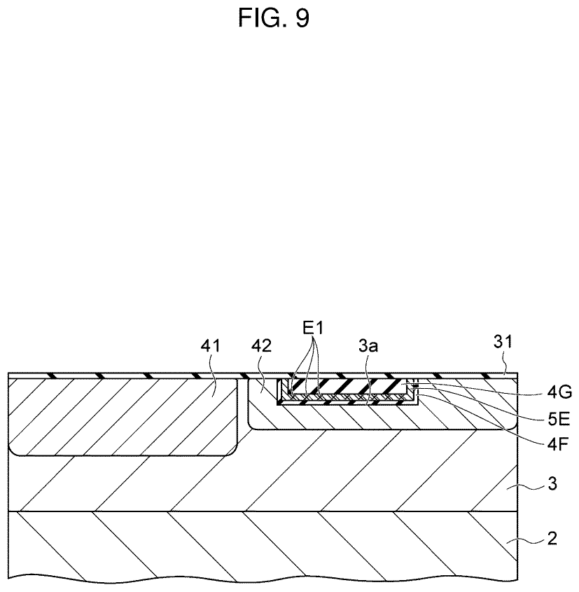

Next, as shown in FIG. 9, an impurity E1 (second impurity) of the first conductivity type is introduced to the second semiconductor layer 5E. In one example, the introduction of the impurity E1 is performed after the fourth step and before a fifth step to be described below. The second impurity is introduced to the second semiconductor layer 5E by ion implantation, for example. The second impurity may be included in the semiconductor layer 22. In one example, in the second step, the second semiconductor layer 5E including the second impurity may be formed. By providing the cover film 31, the surface and the like of the first semiconductor layer 3 is less susceptible to damage when introducing the second impurity to the second semiconductor layer 5E.

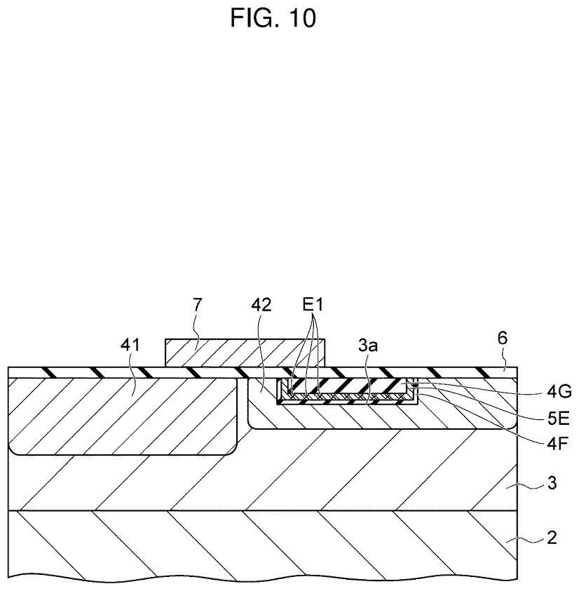

Next, as shown in FIG. 10, the insulating layer 6 is formed on the first semiconductor layer 3 and the insulator 4G (fifth step), and then the gate 7 is formed on the insulating layer 6 (sixth step). In the fifth step, the cover film 31 is first removed. The cover film 31 is removed by wet etching or the like, for example. Then, the insulating layer 6 is formed over the exposed first semiconductor layer 3, insulator 4G, insulating layer 4F, and second semiconductor layer 5E. Next, in the sixth step, a conductive layer is first formed on the insulating layer 6. In one example, a polysilicon layer is formed as the conductive layer. Next, a mask (not shown) is formed on the conductive layer, after which the mask is used to selectively etch the conductive layer. Thus, the gate 7 is formed.

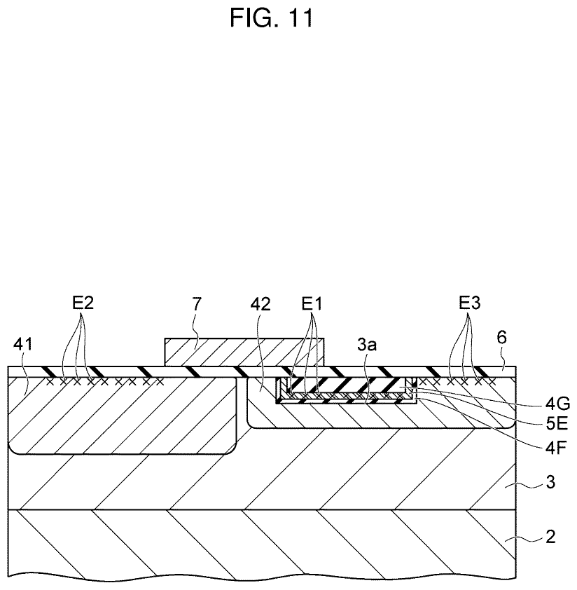

Next, as shown in FIG. 11, impurities E2, E3 (first impurities) of the first conductivity type are introduced to the first semiconductor layer 3 (seventh step). In the seventh step, a mask (not shown) that selectively exposes the insulating layer 6 is formed. In one example, in the insulating layer 6, a portion that overlaps the impurity region 41 but does not overlap the gate 7, and a portion that overlaps the impurity region 42 but does not overlap at least one of the insulating layer 4F, the second semiconductor layer 5E, the insulator 4G, and the gate 7, arc exposed through the mask. Next, the impurities E2 and E3 are introduced to the portions using the mask. The impurity E2 is introduced to the impurity region 41 and the impurity E3 is introduced to the impurity region 42.

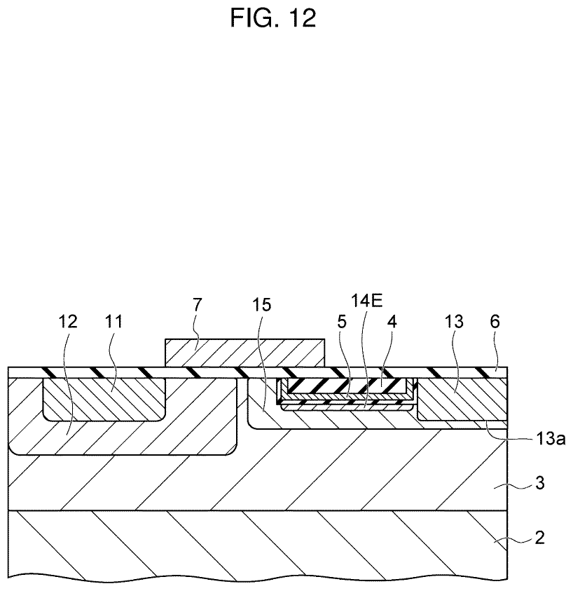

Next, as shown in FIG. 12, by heat treating the first semiconductor layer 3 and the second semiconductor layer 5E, the source region 11 of the first conductivity type surrounded by the body region 12, the drain region 13 of the first conductivity type disposed across the recess 3a from the source region 11, and the first resurf region 14 of the first conductivity type positioned directly below at least the recess 3a are formed in the first semiconductor layer 3 (eighth step). In the eighth step, the substrate 2 is placed in a chamber or the like of a heating device, for example, and the first semiconductor layer 3 and the second semiconductor layer 5E are heat treated. In one example, rapid thermal annealing (RTA) is performed thereon for dozens of minutes to several hours. As a result, the impurities E1 to E3 are diffused in the first semiconductor layer 3. Specifically, by diffusing the impurity E1 included in the second semiconductor layer 5E to the first semiconductor layer 3, the first resurf region 14E is formed. At this time, the impurity E1 is diffused to the first semiconductor layer 3 via the insulating layer 4F, thereby forming the first resurf region 14E. Similarly, by diffusing the impurities E2 and E3 included in the first semiconductor layer 3, the source region 11 and the drain region 13 are formed. The source region 11 is formed in a portion of the impurity region 41 and the drain region 13 is formed in a portion of the impurity region 42, thereby forming the body region 12 and the second resurf region 15.

Next, on the first semiconductor layer 3, the insulating layer 6, the gate 7, and the like, an interlayer insulating film, wiring, vias, and the like (not shown) are formed. Through these steps, the semiconductor device including the LDMOS according to Modification Example 5 is manufactured.

The LDMOSs included in the semiconductor devices according to the embodiment above and Modification Examples 1 to 4 can be manufactured by methods similar to the manufacturing method for the semiconductor device according to Modification Example 5 described above.

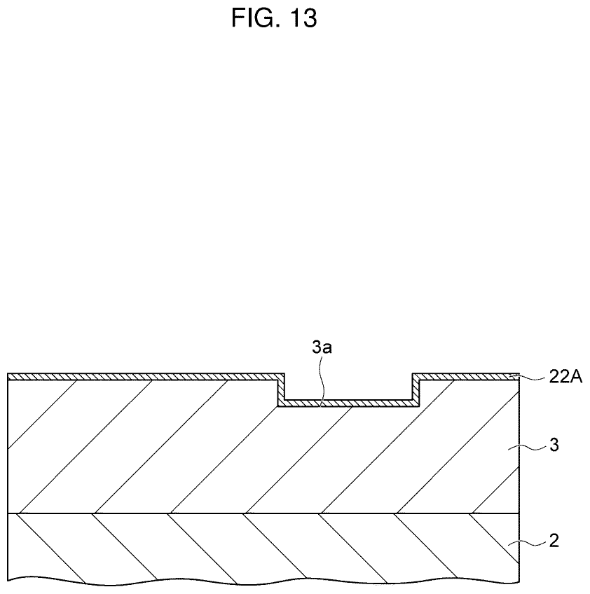

The manufacturing method for the semiconductor device 100 including the LDMOS 102 according to the embodiment above differs from the manufacturing method for the semiconductor device according to Modification Example 5 in terms of the second step. FIG. 13 is a schematic cross-sectional view for describing a portion of a manufacturing method for the semiconductor device of the embodiment above. As shown in FIG. 13, in the embodiment above, after the first step, a semiconductor layer 22A in contact with the bottom surface of the recess 3a is formed after the first step. That is, the embodiment differs from the Modification Example 5 in that the insulating layer 21 (see FIG. 5) is not formed. Also, in the embodiment, the semiconductor layer 22A is selectively etched so as to cover only the bottom surface of the recess 3a. As a result, the second semiconductor layer 5 in contact with the bottom surface of the recess 3a is formed. Next, by performing steps similar to the third to eighth steps of Modification Example 5, the semiconductor device 100 including the LDMOS 102 according to the embodiment above is manufactured.

The manufacturing method for the semiconductor device including the LDMOS according to Modification Example 1 above differs from the manufacturing method for the semiconductor device according to Modification Example 5 in terms of the second step. In Modification Example 1, similar to the embodiment, the semiconductor layer 22A is formed directly over the recess 3a after the first step (see FIG. 13). Next, in Modification Example 1, the semiconductor layer 22A is selectively etched so as to cover the entire recess 3a. As a result, the second semiconductor layer 5A in contact with the entire surface of the recess 3a is formed. Next, by performing steps similar to the third to eighth steps of Modification Example 5, the semiconductor device including the LDMOS 102 according to Modification Example 1 is manufactured.

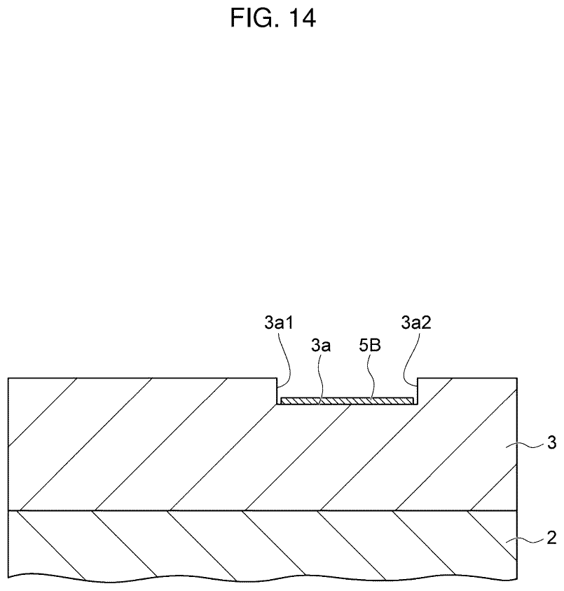

FIG. 14 is a schematic cross-sectional view for describing a portion of a manufacturing method for the semiconductor device of Modification Example 2. The manufacturing method for the semiconductor device including the LDMOS according to Modification Example 2 above differs from the manufacturing method for the semiconductor device according to Modification Example 5 in terms of the second step. In Modification Example 2, similar to the embodiment, the semiconductor layer 22A is formed directly over the recess 3a after the first step (see FIG. 13). Also, in Modification Example 2, the semiconductor layer 22A is selectively etched so as to cover a portion of the bottom surface of the recess 3a. Thus, as shown in FIG. 14, the second semiconductor layer 5E, which is isolated from the side faces 3a1 and 3a2 of the recess 3a, is formed. Next, by performing steps similar to the third to eighth steps of Modification Example 5, the semiconductor device including the LDMOS 102 according to Modification Example 2 is manufactured.

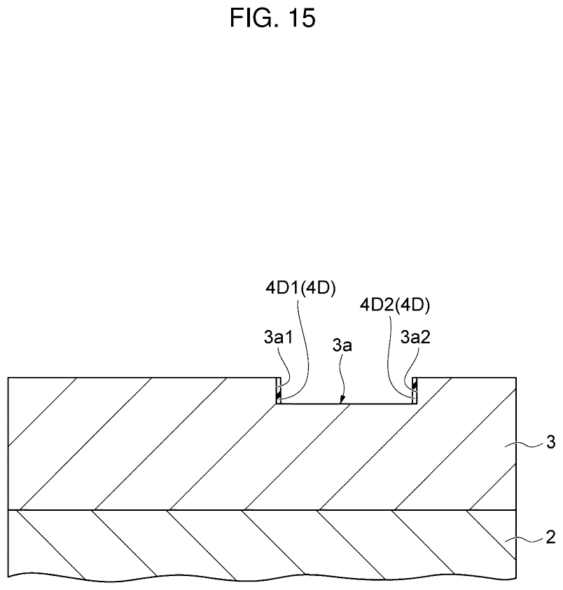

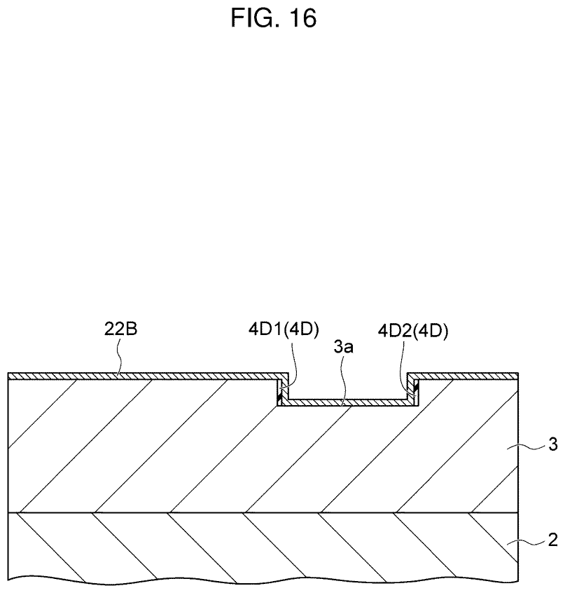

FIGS. 15 and 16 are schematic cross-sectional views for describing a portion of a manufacturing method for the semiconductor device of Modification Example 3. The manufacturing method for the semiconductor device including the LDMOS according to Modification Example 3 above differs from the manufacturing method for the semiconductor device according to Modification Example 5 in terms of the second step. In Modification Example 3, as shown in FIG. 15, the second insulator 4D is formed in the recess 3a after the first step. After the insulating layer 21 (see FIG. 6) is formed in a manner similar to the second step, the insulating layer 21 is selectively etched, for example. As a result, portions of the insulating layer 21 covering the side faces 3a1 and 3a2 of the recess 3a are left remaining, and the second insulator 4D including the first insulating section 4D1 and the second insulating section 4D2 is formed. Next, as shown in FIG. 16, the semiconductor layer 22B is formed. Then, by selectively etching the semiconductor layer 22B, the second semiconductor layer 5C (see FIG. 4D) positioned in the recess 3a is formed. Next, by performing steps similar to the third to eighth steps of Modification Example 5, the semiconductor device including the LDMOS 102 according to Modification Example 3 is manufactured.

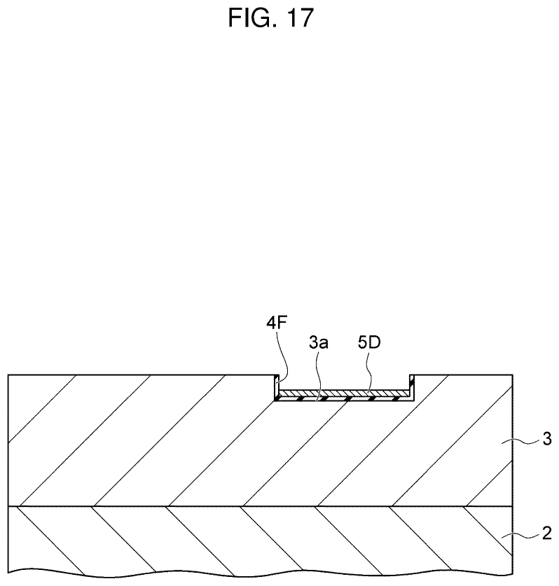

FIG. 17 is a schematic cross-sectional view for describing a portion of a manufacturing method for the semiconductor device of Modification Example 4. The manufacturing method for the semiconductor device including the LDMOS according to Modification Example 4 above differs from the manufacturing method for the semiconductor device according to Modification Example 5 in terms of the second step. In Modification Example 4, as shown in FIG. 17, the insulating layer 4F and the second semiconductor layer 5D (see FIG. 4E) are formed after the first step. In Modification Example 4, the second semiconductor layer 5D is formed by changing etching conditions and the like for the semiconductor layer 22 from Modification Example 5. Next, by performing a step similar to the third step of Modification Example 5, the insulating layer 4F and the insulator deposited in the recess 3a are integrated together. As a result, the insulator 4E (see FIG. 4E) is formed. Next, by performing steps similar to the fourth to eighth steps of Modification Example 5, the semiconductor device including the LDMOS 102 according to Modification Example 4 is manufactured.

The embodiment and the modification examples of the present disclosure were described above, but this disclosure can have even more aspects.

In the embodiment and the modification examples, in addition to the first resurf region, the second resurf region surrounding the first resurf region is formed in the first semiconductor layer, but the configuration is not limited thereto. A configuration may be adopted in which the second resurf region is not formed in the first semiconductor layer, for example.

In the embodiment and the modification examples, the semiconductor device can be applied to a power module used in an inverter circuit that drives an electric motor used as the power source for automobiles (including electric vehicles), electric trains, industrial robots, air conditioning devices, air compressors, fans, vacuum cleaners, dryers, refrigerators, and the like. The semiconductor device can also be applied to a power module used in an inverter circuit of a power generator or the like such as a solar cell or a wind power generator. Alternatively, the semiconductor device can also be applied to a circuit module constituting an analog control power source, a digital control power source, a gate driver, or the like.

An embodiment according to one aspect of the present disclosure and modification examples were described in detail above, but the embodiment and modification examples are merely specific examples used in order to clarify the technical content of the present disclosure. The present disclosure should not be interpreted as being limited to such specific examples, and the scope of the present disclosure is limited only by the attached claims.

Below, characteristic examples derived from the specification and the drawings are disclosed.
[A1] A semiconductor device, including:
a first semiconductor layer of a first conductivity type that is positioned on a substrate; an insulator positioned in a recess provided in the first semiconductor layer;
a second semiconductor layer of the first conductivity type positioned in the recess and at least directly below the insulator;
an insulating layer positioned above the first semiconductor layer and the insulator; and
a gate positioned on the insulating layer,
wherein the first semiconductor layer includes a first contact region and a second contact region of the first conductivity type, a first impurity region of a second conductivity type positioned around the first contact region, and a second impurity region of the first conductivity type in contact with a bottom surface of the second semiconductor layer, and
wherein a diffusion coefficient for impurities in the second semiconductor layer is higher than a diffusion coefficient for impurities in the first semiconductor layer.
[A2] The semiconductor device according to [A1],
wherein the second semiconductor layer has a first portion positioned directly below the insulator and a second portion positioned between the insulator and the first impurity region.
[A3] The semiconductor device according to [A2],
wherein the second impurity region has a first impurity section positioned directly below the first portion and a second impurity section positioned between the first contact region and the second portion.
[A4] The semiconductor device according to any one of [A1] to [A3],
wherein the second semiconductor layer and the second contact region are in contact with each other.
[A5] The semiconductor device according to any one of [A1] to [A4], further including:
a second insulator positioned between the second semiconductor layer and a side face of the recess.
[A6] The semiconductor device according to [A1],
wherein the second semiconductor layer is covered by the insulator.
[A7] The semiconductor device according to any one of [A1] to [A6],
wherein the first semiconductor layer further includes a third impurity region of the first conductivity type positioned around the second impurity region, and
wherein an impurity concentration of the second impurity region is greater than an impurity concentration of the third impurity region.
[A8] A semiconductor device, including:
a first semiconductor layer of a first conductivity type that is positioned on a substrate;
an insulating layer positioned on a surface of a recess provided in the first semiconductor layer;
a second semiconductor layer of the first conductivity type positioned in the recess and on the insulating layer;
an insulator positioned in the recess and on the second semiconductor layer;
a second insulating layer positioned above the first semiconductor layer and the insulator; and
a gate positioned on the second insulating layer,
wherein the first semiconductor layer includes a first contact region and a second contact region of the first conductivity type, a first impurity region positioned around the first contact region, and a second impurity region of the first conductivity type in contact with at least a bottom surface of the insulating layer, and
wherein a diffusion coefficient for impurities in the second semiconductor layer is higher than a diffusion coefficient for impurities in the first semiconductor layer.
[A9] The semiconductor device according to [A8],
wherein the second semiconductor layer has a first portion positioned directly below the insulator and a second portion positioned between the insulator and the first impurity region.
[A10] The semiconductor device according to [A9],
wherein the second impurity region has a first impurity section positioned directly below the first portion and a second impurity section positioned between the first contact region and the second portion.
[A11] The semiconductor device according to any one of [A8] to [A10],
wherein the first semiconductor layer further includes a third impurity region of the first conductivity type positioned around the second impurity region, and
wherein an impurity concentration of the second impurity region is greater than an impurity concentration of the third impurity region.
[A12] A manufacturing method for a semiconductor device, including:
a first step of forming a recess in a first semiconductor layer that is of a first conductivity type and that is positioned on a substrate;
a second step of forming a second semiconductor layer in the recess;
a third step of forming an insulator in the recess so as to cover at least a portion of the second semiconductor layer;
a fourth step of forming a first impurity region of a second conductivity type differing from the first conductivity type in the first semiconductor layer;
a fifth step of forming an insulating layer on the first semiconductor layer and the insulator;
a sixth step of forming a gate on the insulating layer;
a seventh step of introducing a first impurity of the first conductivity type to the first semiconductor layer; and
an eighth step of heat treating the first semiconductor layer and the second semiconductor layer, thereby forming, in the first semiconductor layer, a first contact region of the first conductivity type and surrounded by the first impurity region, a second contact region of the first conductivity type and positioned across the recess from the first contact region, and a second impurity region of the first conductivity type and positioned at least directly below the recess,
wherein, in the eighth step, the second impurity region is formed by diffusing a second impurity of the first conductivity type included in the second semiconductor layer, and
wherein a diffusion coefficient for impurities in the second semiconductor layer is higher than a diffusion coefficient for impurities in the first semiconductor layer.
[A13] The manufacturing method for a semiconductor device according to [A12],
wherein in the second step, the second semiconductor layer including the second impurity of the first conductivity type is formed.
[A14] The manufacturing method for a semiconductor device according to [A12],
further including: a step of introducing the second impurity to the second semiconductor layer after the fourth step and before the fifth step.
[A15] The manufacturing method for a semiconductor device according to any one of [A12] to [A14],
wherein in the second step, a second insulating layer covering a surface of the recess is formed, after which a second semiconductor layer is formed on the second insulating layer.
[A16] The manufacturing method for a semiconductor device according to any one of [A12] to [A15], further including:
a step of forming a third impurity region of the first conductivity type in the first semiconductor layer directly before or directly after the fourth step,
wherein in the eighth step, the second impurity region surrounded by the third impurity region is formed.
[A17] The manufacturing method for a semiconductor device according to any one of [A12] to [A16],
wherein in the second step, the second semiconductor layer in contact with at least a bottom surface of the recess is formed.

What is claimed is:

1. A semiconductor device, comprising:
a first semiconductor layer of a first conductivity type that is positioned on a substrate;
an insulator positioned in a recess provided in the first semiconductor layer;
a second semiconductor layer of the first conductivity type positioned in the recess and at least directly below the insulator;
an insulating layer positioned above the first semiconductor layer and the insulator; and
a gate positioned on the insulating layer,
wherein the first semiconductor layer includes a first contact region and a second contact region of the first conductivity type, a first impurity region of a second conductivity type positioned around the first contact region, and a second impurity region of the first conductivity type in contact with a bottom surface of the second semiconductor layer, and
wherein a diffusion coefficient for impurities in the second semiconductor layer is higher than a diffusion coefficient for impurities in the first semiconductor layer.

2. The semiconductor device according to claim 1,
wherein the second semiconductor layer has a first portion positioned directly below the insulator and a second portion positioned between the insulator and the first impurity region.

3. The semiconductor device according to claim 2,
wherein the second impurity region has a first impurity section positioned directly below the first portion and a second impurity section positioned between the first contact region and the second portion.

4. The semiconductor device according to claim 1,
wherein the second semiconductor layer and the second contact region are in contact with each other.

5. The semiconductor device according to claim 1, further comprising:
a second insulator positioned between the second semiconductor layer and a side face of the recess.

6. The semiconductor device according to claim 1,
wherein the second semiconductor layer is covered by the insulator.

7. The semiconductor device according to claim 1,
wherein the first semiconductor layer further includes a third impurity region of the first conductivity type positioned around the second impurity region, and
wherein an impurity concentration of the second impurity region is greater than an impurity concentration of the third impurity region.

8. A semiconductor device, comprising:
a first semiconductor layer of a first conductivity type that is positioned on a substrate;
an insulating layer positioned on a surface of a recess provided in the first semiconductor layer;
a second semiconductor layer of the first conductivity type positioned in the recess and on the insulating layer;
an insulator positioned in the recess and on the second semiconductor layer;
a second insulating layer positioned above the first semiconductor layer and the insulator; and
a gate positioned on the second insulating layer,
wherein the first semiconductor layer includes a first contact region and a second contact region of the first conductivity type, a first impurity region positioned around the first contact region, and a second impurity region of the first conductivity type in contact with at least a bottom surface of the insulating layer, and
wherein a diffusion coefficient for impurities in the second semiconductor layer is higher than a diffusion coefficient for impurities in the first semiconductor layer.

9. The semiconductor device according to claim 8,
wherein the second semiconductor layer has a first portion positioned directly below the insulator and a second portion positioned between the insulator and the first impurity region.

10. The semiconductor device according to claim 9,
wherein the second impurity region has a first impurity section positioned directly below the first portion and a second impurity section positioned between the first contact region and the second portion.

11. The semiconductor device according to claim 8,
wherein the first semiconductor layer further includes a third impurity region of the first conductivity type positioned around the second impurity region, and
wherein an impurity concentration of the second impurity region is greater than an impurity concentration of the third impurity region.

12. A manufacturing method for a semiconductor device, comprising:
a first step of forming a recess in a first semiconductor layer that is of a first conductivity type and that is positioned on a substrate;
a second step of forming a second semiconductor layer in the recess;
a third step of forming an insulator in the recess so as to cover at least a portion of the second semiconductor layer;
a fourth step of forming a first impurity region of a second conductivity type differing from the first conductivity type in the first semiconductor layer;
a fifth step of forming an insulating layer on the first semiconductor layer and the insulator;
a sixth step of forming a gate on the insulating layer;
a seventh step of introducing a first impurity of the first conductivity type to the first semiconductor layer; and
an eighth step of heat treating the first semiconductor layer and the second semiconductor layer, thereby forming, in the first semiconductor layer, a first contact region of the first conductivity type and surrounded by the first impurity region, a second contact region of the first conductivity type and positioned across the recess from the first contact region, and a second impurity region of the first conductivity type and positioned at least directly below the recess,
wherein, in the eighth step, the second impurity region is formed by diffusing a second impurity of the first conductivity type included in the second semiconductor layer, and
wherein a diffusion coefficient for impurities in the second semiconductor layer is higher than a diffusion coefficient for impurities in the first semiconductor layer.

13. The manufacturing method for a semiconductor device according to claim 12,
wherein in the second step, the second impurity is included in the second semiconductor layer.

14. The manufacturing method for a semiconductor device according to claim 12, further comprising:
a step of introducing the second impurity to the second semiconductor layer after the fourth step and before the fifth step.

15. The manufacturing method for a semiconductor device according to claim 12,
wherein in the second step, a second insulating layer covering a surface of the recess is formed, after which the second semiconductor layer is formed on the second insulating layer.

16. The manufacturing method for a semiconductor device according to claim 12, further comprising:
a step of forming a third impurity region of the first conductivity type in the first semiconductor layer directly before or directly after the fourth step,
wherein in the eighth step, the second impurity region that is formed is surrounded by the third impurity region.

17. The manufacturing method for a semiconductor device according to claim 12,
wherein in the second step, the second semiconductor layer in contact with at least a bottom surface of the recess is formed.
